(19) United States
(12) Patent Application Publication
(10) Pub. No.: US 2025/0220836 A1
(43) Pub. Date: Jul. 3, 2025

(54) MACHINE HOUSING AND ELECTRONIC DEVICE

(71) Applicant: AAC ACOUSTIC TECHNOLOGIES (SHENZHEN) CO., LTD., Shenzhen (CN)

(72) Inventor: Zhenhua Zang, Shenzhen (CN)

(21) Appl. No.: 18/666,821

(22) Filed: May 17, 2024

Related U.S. Application Data
(63) Continuation of application No. PCT/CN2023/143476, filed on Dec. 29, 2023.

(51) Int. Cl. H05K 5/03

(52) U.S. Cl. CPC H05K 5/03

(57) ABSTRACT

The present disclosure relates to the technical field of machine housings, and provides a machine housing and an electronic device. The machine housing is applied to a mobile electronic terminal. The machine housing includes: an inner shell including an inner shell body and an accommodating groove formed by recessing from one side of the inner shell body; and an outer shell in an annular shape, wherein the housing extends around a periphery of the inner shell body and is fixed to the inner shell body. The outer shell is made of a titanium alloy material, the inner shell body is made of a metal material other than the titanium alloy material; and the outer shell and the inner shell body are fixedly molded into an integrated structure by a hot isostatic pressing process. Compactness, uniformity and performance of the machine housing may be improved by the hot isostatic pressing process.

### TECHNICAL FIELD

The present disclosure relates to the technical field of housings, and in particular, to a machine housing and an electronic device.

### BACKGROUND

A titanium alloy is a light, high-strength and corrosion-resistant material, and has a density generally 4.51 g/cm², which is only 60% of the density of steel. If the machine housing is prepared by the titanium alloy material, it will have high-strength performance and excellent corrosion resistance, its texture and quality may be improved to make it more delicate and fashionable, and appearance can have more choices. If an inner cavity of the machine housing adopts other light and low-cost metal materials, the processing time and the overall weight of the machine housing may be greatly reduced, meanwhile, the cost is reduced. For example, the aluminum alloy has good corrosion-resistance, oxide film thereof is compact so that the ductility and the processing performance are good, and it can be repeatedly used. If the inner cavity of the machine housing adopts a recyclable metal material similar to aluminum, the lower cost may be achieved, and the effect of protecting environment is achieved.

There are mainly two kinds of methods for processing the machine housing in the related art. In the first kind of method for processing the machine housing, a whole machine housing is forged by a titanium plate, and then processed by CNC (computer numerical control machine tool), 3D printing, MIM (metal injection molding) and so on. This processing method has the defects of high cost, heavy overall weight and serious voluntary waste. In the second kind of method for processing the machine housing, the titanium alloy material and aluminum material are compounded by means of thermal compounding, and then forged, CNC, welded and injection molded to form a frame body. Then CNC, T treatment, injection molding and post-processing are performed on the frame body. Although this processing method can make the machine housing relatively thin, its lightness may not meet the ideal requirement, and the overall cost is high, the surface effect and waterproof performance are poor. That is, the methods for processing the machine housing in the related art mainly have the defects of low compactness, poor uniformity and poor performance (hardness, yield strength, tensile strength and elongation).

Therefore, it is necessary to provide a new machine housing to solve the above problems.

### SUMMARY

An object of the present disclosure is to provide a machine housing and an electronic device to solve the problems of low compactness, poor uniformity and poor performance of the machine housing in the related art.

In a first aspect, the present disclosure provides a machine housing applied to a mobile electronic terminal. The machine housing includes:
an inner shell including an inner shell body and an accommodating groove formed by recessing from one side of the inner shell body; and
an outer shell in an annular shape, wherein the housing extends around a periphery of the inner shell body and is fixed to the inner shell body.

The outer shell is made of a titanium alloy material, the inner shell body is made of a metal material other than the titanium alloy material; and the outer shell and the inner shell body are fixedly molded into an integrated structure by a hot isostatic pressing process.

Optionally, the hot isostatic pressing process has a heating temperature ranging from 1000° C. to 2000° C. and a working pressure of 200 MPa.

Optionally, a periphery of the inner shell body protrudes and extends to form a step portion; a concave portion is formed by recessing at a position of an inner periphery of the outer shell corresponding to the step portion; and the step portion extends into the concave portion.

Optionally, a plurality of step portions and a plurality of concave portions are provided, the plurality of step portions are arranged at intervals along the periphery of the inner shell body, the plurality of concave portions are arranged at intervals along an inner periphery of the outer shell, and the plurality of step portions each extends into one corresponding concave portion of the plurality of concave portions.

Optionally, the plurality of step portions are arranged at equal intervals.

Optionally, the outer housing includes a first outer shell body provided around a part of the periphery of the inner shell body and a second outer shell body provided around other parts of the periphery of the inner shell body; two gaps are respectively formed at connections of two ends of the first outer shell body and two ends of the second outer shell body; two opposite sides of the inner shell body are respectively provided with two reinforcing portions that protrude and extend outward; the two reinforcing portions respectively pass through the two gaps and are fixed to the outer shell.

Optionally, the reinforcing portion includes two parallel first protruding portions formed by protruding and extending from the periphery of the inner shell body and a second protruding portion connecting a middle position of the two first protruding portions, and the two first protruding portions and the second protruding portion jointly enclose two grooves located on two opposite sides of the second protruding portion; two ends of the first outer shell body and two ends of the second outer shell body are respectively provided with an inserting portion formed by protruding and extending outward, and two inserting portions located at two adjacent ends of the first outer shell body and the second outer shell body are respectively sandwiched in two corresponding grooves of a same reinforcing portion.

Optionally, the housing body is made of an aluminum metal material; a transition layer is sandwiched at a joint between the outer shell and the inner shell body; a portion of the transition layer close to the housing body is made of the aluminum metal material, and a portion of the transition layer close to the outer shell is made of a titanium alloy material.

In a second aspect, the present disclosure provides an electronic device, and a housing of the electronic device is a machine housing described above.

Compared with the related art, the outer shell of the machine housing is made of the titanium alloy material, the inner shell body is made of a metal material other than the titanium alloy material, and the outer shell and the inner shell body are limited to be respectively processed and formed by the hot isostatic pressing process, so that the compactness, the uniformity and the performance of the machine housing may be improved by the hot isostatic pressing process.

### BRIEF DESCRIPTION OF DRAWINGS

In order to more clearly explain the embodiments of the present disclosure or the technical solution in the related art, the drawings to be used in the description of the embodiments or the related art will be briefly described below. The drawings in following description are some embodiments of the present disclosure. For those skilled in the art, other drawings may also be obtained based on these drawings.

FIG. 1 is a schematic diagram of a three-dimensional structure of a machine housing according to an embodiment of the present disclosure;

FIG. 2 is a structural decomposition diagram of a machine housing according to an embodiment of the present disclosure; and

FIG. 3 is a schematic diagram of the material ratio of a part of a cross section of a machine housing according to an embodiment of the present disclosure.

In the drawings, 100: machine housing; 1: inner shell; 11: inner shell body; 111: step portion; 112: reinforcing portion; 1121: first protruding portion; 1122: second protruding portion; 1123: groove; 12: accommodating groove; 2: machine housing; 21: concave portion; 22: first outer shell body; 23: second outer shell body; 24a: first inserting portion 24b: second inserting portion; 3: transition layer.

### DESCRIPTION OF EMBODIMENTS

Unless otherwise defined, all technical and scientific terms used herein have the same meaning as commonly understood by those belonging to the technical field of the present disclosure. The terms used herein in the specification of the present disclosure are only for the purpose of describing specific embodiments and are not intended to limit the present disclosure. The terms “including” and “having” and any variations thereof in the specification and claims of the present disclosure and the description of the above drawings are intended to cover non-exclusive inclusion. The terms “first”, “second” and the like in the specification and claims of the present disclosure or the above drawings are used to distinguish different objects, and are not used to describe a specific order.

The “embodiments” mentioned herein means that particular features, structures or characteristics described with reference to the embodiments may be included in one or more embodiments of the present disclosure. Phrases appearing at various positions of the specification neither always refer to the same embodiments, nor separate or alternative embodiments that are mutually exclusive with other embodiments. It is explicitly and implicitly understood by those skilled in the art that the embodiments described herein may be combined with other embodiments.

It should be noted that the expressions “upper”, “lower”, “left”, “right” and the like mentioned in the embodiments of the present disclosure are described with reference to the placement states in the drawings, and should not be construed as limiting embodiments of the present disclosure. In addition, it should be further understood that, when referring to an element that constitutes “above” or “below” another element, it is possible that the element directly constitutes “above” or “below” another element, or it is possible that the element constitutes “above” or “below” another element through an intermediate element.

The technical solution as described in some embodiments of the present disclosure may be described below clearly and fully with reference to the drawings in some embodiments of the present disclosure, and apparently some embodiments to be described below are only a part but not all of the embodiments of the present disclosure. All other embodiments obtained by those of ordinary skill in the art based on the embodiments of the present disclosure should fall within the protection scope of the present disclosure.

### Embodiment 1

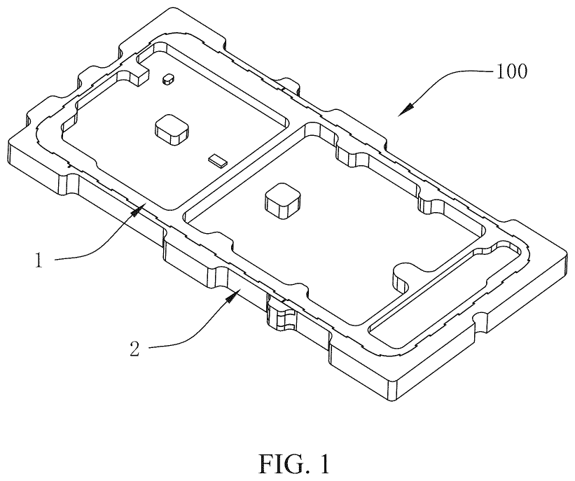

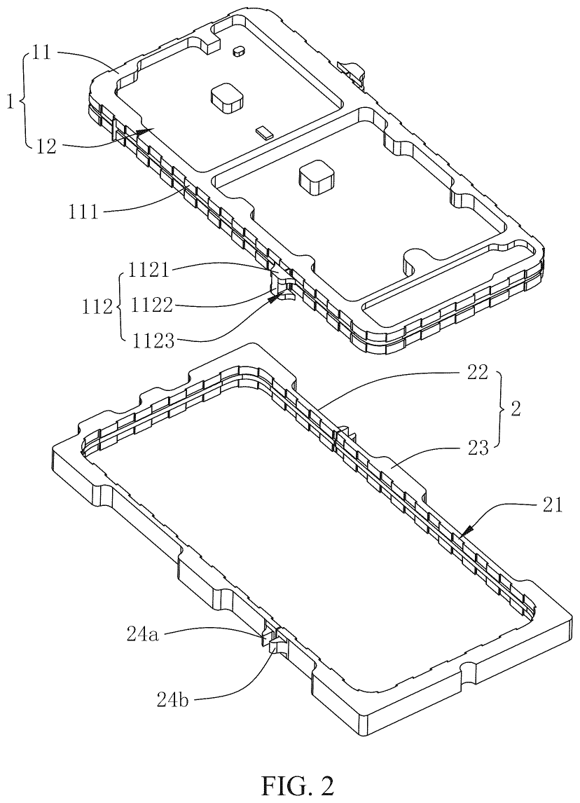

The present disclosure provides a machine housing 100 applied to a mobile electronic terminal. As shown in FIG. 1 and FIG. 2, the machine housing 100 includes an inner shell 1 and an outer shell 2. The inner shell 1 includes an inner shell body 11 and an accommodating groove 12 formed by recessing one side of the inner shell body 11. The outer shell 2 is annular. The outer shell 2 is fixed to the inner shell body 11 around the periphery of the inner shell body 11. The outer shell 2 is made of a titanium alloy material. The inner shell body 11 is made of a metal material other than the titanium alloy material. The outer shell 2 and the inner shell body 11 are fixedly molded into an integrated structure by a hot isostatic pressing process.

The hot isostatic pressing is also referred to as HIP. It is a process production technology integrating high temperature and high pressure, and a high-pressure inert gas in a closed container is used as a pressure transmission medium. In an embodiment, the hot isostatic pressing process has a heating temperature ranging 1000° C. to 2000° C. and a working pressure of 200 MPa.

The outer shell 2 may be an annular structure formed integrally, or may be an annular structure enclosed by multiple sections.

In an embodiment, multiple accommodating grooves 12 are provided at intervals. It can be appreciated that, one accommodating groove 12 may be provided according to actual requirements.

The periphery of the inner shell body 11 protrudes and extends to form a step portion 111. A concave portion 21 is formed by recessing at a position of an inner periphery of the outer shell 2 corresponding to the step portion 111. The step portion 111 extends into the concave portion 21.

In an embodiment, multiple step portions 111 and multiple concave portions 21 are included. The step portions 111 are arranged at intervals along the periphery of the inner shell body 11, the concave portions 21 are arranged at intervals along the inner periphery of the outer shell 2. Each step portion 111 extends into one corresponding concave portion 21. This design may increase the fixed area between the inner shell body 11 and the outer shell 2 by the step portion 111 and the concave portion 21, so as to improve the connection strength between the inner shell body 11 and the outer shell 2. In order to increase the connection strength between the inner shell body 11 and the outer shell 2, the step portions 111 are arranged at equal intervals. It can be appreciated that the step portions 111 may also be arranged at unequal intervals according to actual requirements.

In an embodiment, the outer shell 2 includes a first outer shell body 22 provided around a part of a periphery of the inner shell body 11 and a second outer shell body 23 provided around other parts of the periphery of the inner shell body 11. Two gaps are respectively formed at connections of two ends of the first outer shell body 22 and two ends of the second outer shell 23. Since the outer shell 2 is divided into the first outer shell body 22 and the second outer shell body 23, there are gaps between two ends of the first outer shell body 22 and two corresponding ends of the second outer shell body 23, that is, there are two gaps. Meanwhile, with such configuration, the outer shell 2 may be better fixed to the periphery of the inner shell 1, and processing is convenient.

Two reinforcing portions 112 that protrudes and extends are respectively provided on two opposite sides of the inner shell body 11. The two reinforcing portions 112 respectively pass through two gaps and are fixed to the outer shell 2.

In an embodiment, the reinforcing portion 112 includes two parallel first protruding portions 1121 formed by protruding and extending from the periphery of the inner shell body 11 and a second protruding portion 1122 connecting a middle position of the two first protruding portions 1121. The first protruding portion 1121 and the second protruding portion 1122 jointly enclose two grooves 1123 located on two opposite sides of the second protruding portion 1122. Two ends of the first outer shell body 22 and two ends of the second outer shell body 23 are respectively provided with an inserting portion formed by protruding and extending outward.

Two inserting portions located at two adjacent ends of the first outer shell body 22 and the second outer shell 23 are respectively sandwiched in two corresponding grooves 1123 of a same reinforcing portion 112. This design may increase the fixed area between the inner shell body 11 and the outer shell 2 to improve the connection strength between the inner shell body 11 and the outer shell 2.

An inserting portion of the end portion of the first outer shell 22 is a first inserting portion 24a. The first inserting portion 24a extends to the groove 1123 on one side of the second protruding portion 1122. An inserting portion at the end portion of the second outer shell 23 is a second inserting portion 24b. The second inserting portion 24b extends to the groove 1123 on the other side of the second protruding portion 1122.

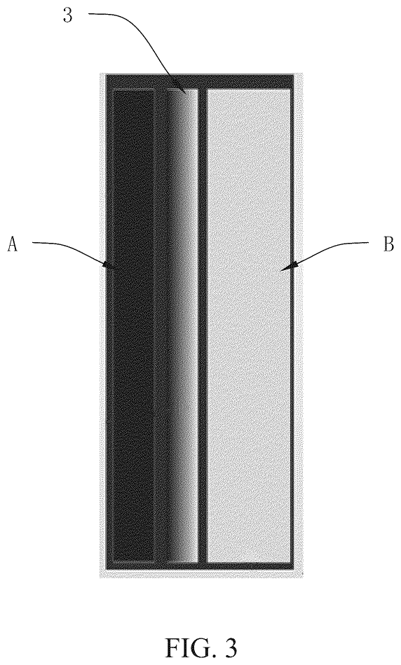

In an embodiment, as shown in FIG. 3, the inner shell body 11 is made of an aluminum metal material. A transition layer 3 is sandwiched at a joint between the outer shell 2 and the inner shell body 11. A portion of the transition layer 3 close to the inner shell body 11 is made of the aluminum metal material, and a portion of the transition layer 3 close to the outer shell 2 is made of the titanium alloy material. This design may improve the connection strength between the outer shell 2 and the inner shell body 11. A represents the titanium alloy material, and B represents the aluminum material.

In an embodiment, a production process of the machine housing 100 is as follows: preparing titanium powder-mold forming-first hot isostatic pressing process-first heat treatment-coating treatment or hole treatment-mold loading-loading a metal material other than aluminum powder or titanium alloy materials-second hot isostatic pressing process-second heat treatment-CNC glue grabbing structure treatment-nanopore treatment professional line body-injection molding-CNC important structure treatment-anode treatment-polishing treatment-surface treatment-PVD (physical vapor deposition) treatment-assembling-checking-finished product shipment. The first hot isostatic pressing process is to process the outer shell 2, and the second hot isostatic pressing process is to process the inner shell 1.

In the solution of thermal compounding process of titanium aluminum plate, TA2 or TA4 thermally compounds with recycled 6-series aluminum. In its performances, a hardness is 350HV1, a yield strength is greater than or equal to 850 MPa, a tensile strength is greater than or equal to 950 MPa, and an elongation is greater than or equal to 15%; appearance is sand blasted and wire drawn; the cost is high; and the middle plate needs to be welded and is easy to be cracked. In an embodiment, in the solution of hot isostatic pressing process, the TA2, Tc4 or high-strength aluminum alloy is compounded with high-strength aluminum. In its performances, a hardness ranges from 350 HV1 to 400HV1 (high compactness), a yield strength is greater than or equal to 950 MPa, a tensile strength is greater than or equal to 1050 MPa, and an elongation is greater than or equal to 15%; the appearance is sand blasted, wire drawn and mirror polished; the cost is medium; the compactness is good, welding is not required, cracking risk is small, and air tightness is good.

In an embodiment, the outer shell 2 of the machine housing 100 is made of a titanium alloy material, the inner shell body 11 is made of a metal material other than the titanium alloy material, and the outer shell 2 and the inner shell body 11 are respectively processed and formed by a hot isostatic pressing process, so that the compactness, uniformity, and performance of the machine housing 100 are improved by the hot isostatic pressing process.

In addition, the machine housing 100 in the embodiments further has following technical effects.
1. By adopting a combined solution of the hot isostatic pressing process, the appearance material may be more precise, the inner cavity may be processed into a complex 3D structure, and the shell 100 may be lighter by using a lighter material.
2. Good compactness and no sand holes. In addition to wire drawing and sand blasting effects, the surface may also be made into a highlight effect to meet more requirements of market consumers.
3. The material has a high production efficiency, and may be recovered to improve environmental protection rate and reduce environmental pollution.
4. When the shell is designed structurally to be applied to 3C products (electronic products) such as mobile phones, tablets and watches, it has relatively low cost and it is more versatile.
5. In the middle of the process, a middle plate is not required to be cast for secondary welding, so that overall rigidity is strong, reducing problems of falling off, fracture and the like caused at the welding spot due to casting the middle plate.
6. Overall processing has a low cost, resource waste is reduced, and productivity and market applications are improved.
7. The comprehensive performance ranges wide, which not only may achieve ultra-strong corrosion-resistance and high strength, but also may adopt light and thin materials to design a complex structure of the inner shell, thereby reducing overall weight.
8. Selecting the above materials and processes obtains wide application. It may be not only applied to complex and high-performance mobile phones, and may be also applied to popular sports watches, and even may meet the requirements of ultra-thin tablets and the like.

### Embodiment 2

The present disclosure provides an electronic device. A housing of the electronic device is a machine housing 100 described in Embodiment 1.

The electronic device is a mobile phone, a watch, a tablet computer, and the like.

Since the electronic device in this embodiment includes the machine housing 100 described in Embodiment 1, it can achieve the technical effect achieved by the machine housing 100 described in Embodiment 1, which are not elaborated herein.

It should be noted that the various embodiments described above with reference to the accompanying drawings are only used to illustrate the present disclosure and not to limit the scope of the present disclosure, and those skilled in the art should understand that modifications or equivalent substitutions made to the present disclosure without departing from the spirit and scope of the present disclosure shall all fall within the scope of the present disclosure. Furthermore, words appearing in singular form include plural forms, and vice versa. Additionally, unless specifically stated, all or a portion of any embodiment may be used by combining with all or a portion of any other embodiment.

1. A machine housing applied to a mobile electronic terminal, the machine housing comprising:
an inner shell comprising an inner shell body and an accommodating groove formed by recessing from one side of the inner shell body; and
an outer shell in an annular shape, wherein the housing extends around a periphery of the inner shell body and is fixed to the inner shell body;
wherein the outer shell is made of a titanium alloy material, the inner shell body is made of a metal material other than the titanium alloy material; and
the outer shell and the inner shell body are fixedly molded into an integrated structure by a hot isostatic pressing process.

2. The machine housing as described in claim 1, wherein the hot isostatic pressing process has a heating temperature ranging from 1000° C. to 2000° C. and a working pressure of 200 MPa.

3. The machine housing as described in claim 1, wherein a periphery of the inner shell body protrudes and extends to form a step portion; a concave portion is formed by recessing at a position of an inner periphery of the outer shell corresponding to the step portion; and the step portion extends into the concave portion.

4. The machine housing as described in claim 3, wherein a plurality of step portions and a plurality of concave portions are provided, the plurality of step portions are arranged at intervals along the periphery of the inner shell body, the plurality of concave portions are arranged at intervals along an inner periphery of the outer shell, and the plurality of step portions each extends into one corresponding concave portion of the plurality of concave portions.

5. The machine housing as described in claim 4, wherein the plurality of step portions are arranged at equal intervals.

6. The machine housing as described in claim 1, wherein the outer housing comprises a first outer shell body provided around a part of the periphery of the inner shell body and a second outer shell body provided around other parts of the periphery of the inner shell body; two gaps are respectively formed at connections of two ends of the first outer shell body and two ends of the second outer shell body; two opposite sides of the inner shell body are respectively provided with two reinforcing portions that protrude and extend outward; the two reinforcing portions respectively pass through the two gaps and are fixed to the outer shell.

7. The machine housing as described in claim 6, wherein the reinforcing portion comprises two parallel first protruding portions formed by protruding and extending from the periphery of the inner shell body and a second protruding portion connecting a middle position of the two first protruding portions, and the two first protruding portions and the second protruding portion jointly enclose two grooves located on two opposite sides of the second protruding portion; two ends of the first outer shell body and two ends of the second outer shell body are respectively provided with an inserting portion formed by protruding and extending outward, and two inserting portions located at two adjacent ends of the first outer shell body and the second outer shell body are respectively sandwiched in two corresponding grooves of a same reinforcing portion.

8. The machine housing as described in claim 1, wherein the housing body is made of an aluminum metal material; a transition layer is sandwiched at a joint between the outer shell and the inner shell body; a portion of the transition layer close to the housing body is made of the aluminum metal material, and a portion of the transition layer close to the outer shell is made of a titanium alloy material.

9. An electronic device, wherein a housing of the electronic device is a machine housing as described in claim 1.
